(19) United States
(12) Patent Application Publication
(10) Pub. No.: US 2003/0111342 A1
(43) Pub. Date: Jun. 19, 2003

(54) Sputter coating apparatus

(75) Inventors: Robert W. Choquette, Sarasota, FL (US); Richard Glanz, Sarasota, FL (US)

Correspondence Address: Charles J. Prescott, P.A., Suite 115, 2033 Wood Street, Sarasota, FL, 34237, US

(73) Assignee: CompuVac Systems, Inc., Sarasota, FL

(21) Appl. No.: 10/023,263

(22) Filed: Dec. 18, 2001

(51) Int. Cl. C23C 14/34

(52) U.S. Cl. 204/298.25; 204/298.11

(57) ABSTRACT

A sputter coating apparatus for depositing a thin uniform material coating onto exposed surfaces of objects. The apparatus includes a vacuum chamber having one or more sealably closable doors through which objects treated by sputter coating are loaded into and removed therefrom and a support positionable within the chamber for supporting the objects to be sputter coated. A vacuum source establishes a vacuum in the chamber when the door is closed and the objects are held by the support within the chamber. A sputtering target formed of a material to be sputter coated onto the objects is operably connected within the chamber and spaced apart from the objects. A process gas inlet is operably connected to introduce a process gas such as argon or nitrous oxide into said chamber after a vacuum is established. A high voltage source is operably connected between the objects on the support within the chamber and the sputtering target and arranged to pass through said process gas, the voltage source sufficient to produce an ion plasma formed of some of the material vaporized from the target which is uniformly deposited onto the objects. A protective cover is moveable between a first position away from the target when the door is closed and the apparatus is in operation and a second position of sealing engagement over the target to substantially maintain the vacuum and process gas condition surrounding the target while the apparatus was in operation when the door is opened for loading and unloading of the objects.

### BACKGROUND OF THE INVENTION

1. Scope of Invention

This invention relates generally to systems for coating objects by sputtering deposition, and more particularly to a sputtering deposition system having a uniquely configured cover for the sacrificial target during time periods of loading and unloading the vacuum chamber.

2. Prior Art

The sputtering deposition of materials is well known and includes the process of material removal from a target material by its bombardment with highly energized ions formed after high-energy electrons are emitted from the target material by placing a high RF or dc voltage between the target and the objects to be coated. These emitted electrons ionize process gas such as argon placed within the vacuum chamber after it has been substantially evacuated of air up to 100 m Torr vacuum pressure.

The process gas ions then form a plasma, an electrically neutral associations of electrons and positive ions. The plasma is caused by the emitting of electrons from the target material. The plasma ion accelerate and strike the target causing atoms to be ejected from the target material which are then deposited on the objects having previously been placed within the vacuum chamber.

During loading and unloading of the vacuum chamber, the sacrificial target material is typically exposed to atmospheric conditions after having been at least partially spent during previous sputter coating cycles. A conventionally sized target material contains sufficient solid material to sputter coat several loads of objects unless the target material becomes so contaminated as to lose the ability to emit atoms responsive to the highly energized ions within the processed gas.

The present invention, which might, in one aspect, be referred to as a “load locked target”, provides a sealing cover over the target material during times of loading and unloading so that the high level of vacuum in combination with the addition of the process gas in the vacuum chamber during each cycle is always maintained. By doing so, the poisoning of the target material is virtually eliminated and substantially higher utilization of the target material is achieved. Additionally, the vacuum chamber of the present invention is capable of achieving faster cycle times and less scrap or yellowing of the coatings on objects as a result of the atmospheric contamination of the target material when the vacuum chamber is open. Where aluminum is the sputtering target material, better photometrics or aluminum brightness and appearance is achieved on the objects which are sputter coated by the present invention.

### BRIEF SUMMARY OF THE INVENTION

This invention is directed to a sputter coating apparatus for depositing a thin uniform material coating onto exposed surfaces of objects. The apparatus includes a vacuum chamber having one or more sealably closable doors through which objects treated by sputter coating are loaded into and removed therefrom and a support positionable within the chamber for supporting the objects to be sputter coated. A vacuum source establishes a vacuum in the chamber when the door is closed and the objects are held by the support within the chamber. A sputtering target formed of a material to be sputter coated onto the objects is operably connected within the chamber and spaced apart from the objects. A process gas inlet is operably connected to introduce a process gas such as argon into said chamber after a vacuum is established. A high voltage source is operably connected between the objects on the support within the chamber and the sputtering target and arranged to pass through said process gas, the voltage source sufficient to produce an ion plasma formed of some of the material vaporized from the target which is uniformly deposited onto the objects. A protective cover is moveable between a first position away from the target when the door is closed and the apparatus is in operation and a second position of sealing engagement over the target to substantially maintain the vacuum condition surrounding the target while the apparatus was in operation when the door is opened for loading and unloading of the objects.

It is therefore an object of this invention to provide a sputter coating vacuum chamber which includes the ability to protectively maintain the vacuum environment surrounding the sputter coating target material during times of loading and unloading of the vacuum chamber to prevent target poisoning from the monomer used during the top coating cycle which would otherwise greatly reduce the yield of the machine's production parts.

It is another object of this invention to achieve enhanced sputter coating production aspects including the substantial elimination of target material poisoning, higher target material utilization, faster cycle times, much less scrap coatings on objects and brighter aluminum or sputtered material appearance because of better photometrics associated with uncontaminated target materials.

In accordance with these and other objects which will become apparent hereinafter, the instant invention will now be described with reference to the accompanying drawings.

### BRIEF DESCRIPTION OF THE DRAWINGS

FIG. 1 is a top plan schematic view of a vacuum chamber material deposition system of the present invention.

FIG. 2 is a front elevation view of the invention of FIG. 1.

FIG. 3 is a partially sectioned top plan schematic view of the invention of FIG. 1.

FIG. 4 is an enlarged portion of FIG. 3.

### DETAILED DESCRIPTION OF THE INVENTION

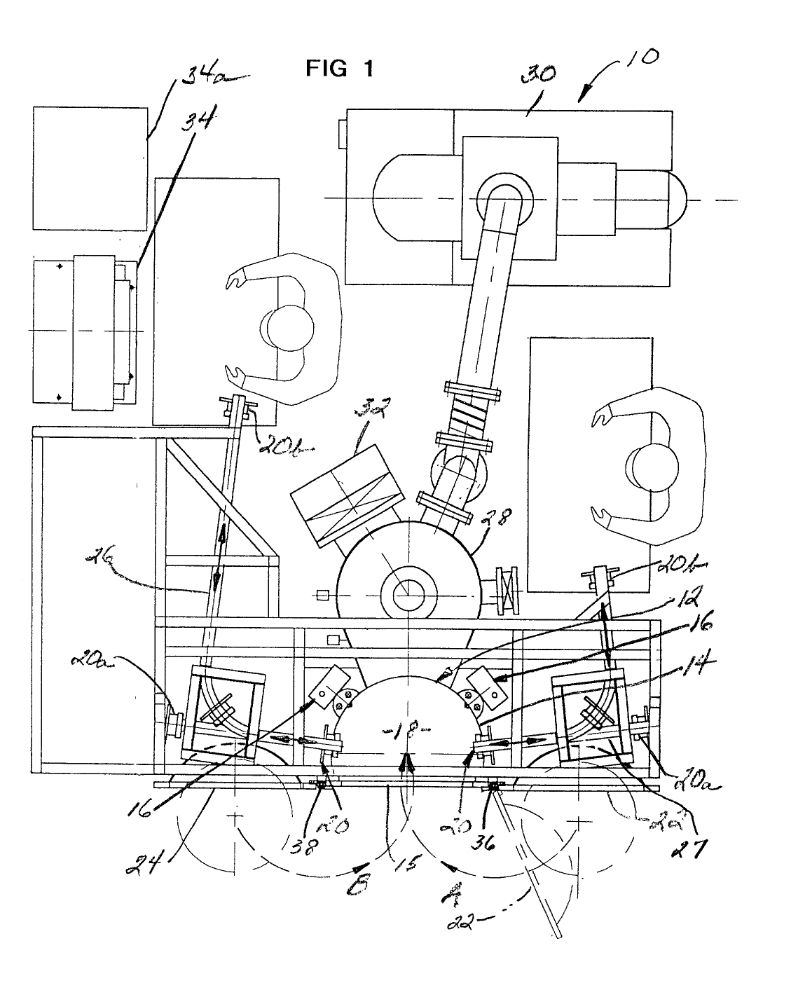

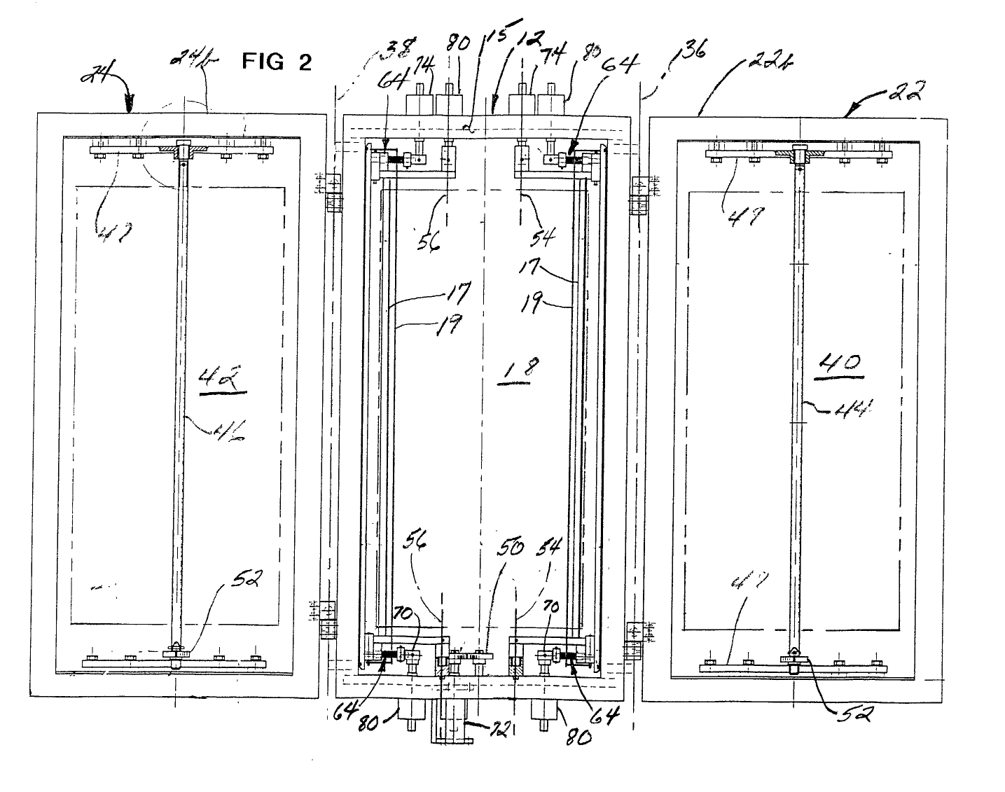

Referring now to the drawings, and first to FIGS. 1 and 2, the invention is shown generally at numeral 10 in FIG. 1 and includes a sputter coating apparatus 12 which generally includes a vacuum chamber 14 and two spaced longitudinally extending polymerization apparatus 16. The polymerization apparatus 16 is described in detail in U.S. Pat. No. 5,895,531, which is incorporated herein by reference.

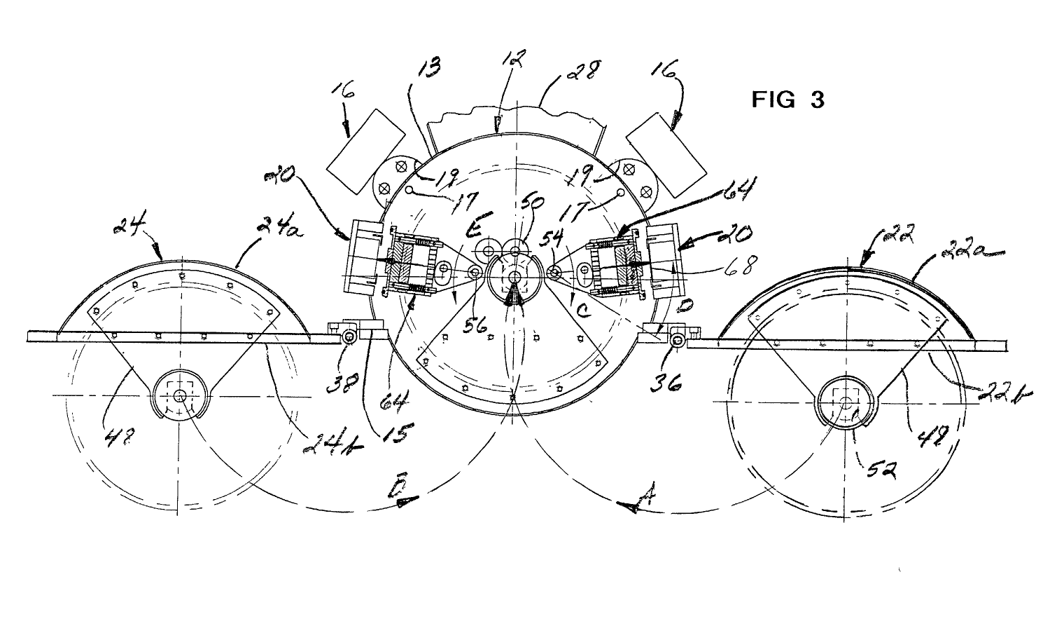

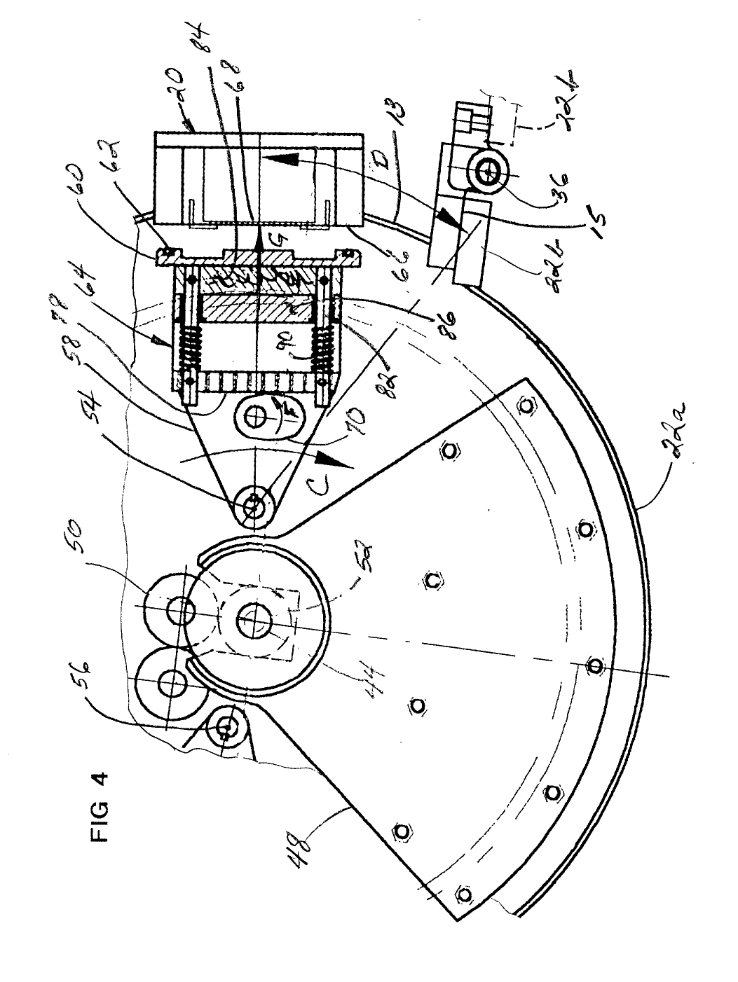

The sputter coating apparatus 12 also includes two spaced apart elongated sputtering target assemblies 20 which are positioned as best seen in FIGS. 1 and 3 adjacent to the opening 15 of the vacuum chamber 14. Each of these sputtering target assemblies 20, which are generally coextensive with the longitudinal axis of the elongated cylindrical vacuum chamber 14 itself. Each includes an elongated sacrificial sputtering target plate 68 as best seen in FIG. 4. The apparatus 12 further includes swingably or pivotally closeable doors 22 and 24, which are each hingedly connected about an upright axis 36 or 38, respectively, which extend generally parallel to the opening 15. Each of these doors 22 and 24 is intended to be individually closed to seal the vacuum chamber 14. The cylindrical surfaces 22a and 24a are configured to support reel mounting plates 48 and the corresponding upright reel support shafts 44. Top and bottom reel mounting plates 48 and the elongated reel shaft 44 form an assembly for supporting objects to be placed into the vacuum chamber 12. These objects (not shown) are loaded onto the reel assembly as desired when either of the doors 22 and 24 are in the open position as shown in FIGS. 2 and 3. After one of these doors 22 or 24 has been loaded with objects to be sputter coated, it is closed in the direction of arrow A or B and sealingly locked in place against opening 15. A driven gear 52 rigidly connected to the lower end of reel shaft 44 engages with driving gear 50 so that drive motor 72 will cause the reel shaft 44 and the entire reel assembly with objects loaded thereon to rotate in the direction of arrow C in FIGS. 3 and 4 within the interior 18 of the vacuum chamber 12 at a desired rate of rotation.

Turning now to FIG. 1, the rest of the sputtering system 10 includes a plenum 28 which facilitates the evacuation of air from the interior 18 of the chamber 13 to draw the vacuum atmosphere within the chamber 13 down to up to 100 m Torr pressure level during each coating operation. A polypod 32 is operably connected to the refrigeration unit 34a. Rotary vane pump 30 interconnected with the plenum 28 effects the depressurization of the chamber 13. Polymer reservoir 34, interconnected to the polymerization apparatus 16 adjacent thereto, transfers the polymerization material to each of the polymerization apparatus 16.

Referring now particularly to FIGS. 2 to 4, each of the protective target cover assemblies are shown generally at numeral 64 positioned in the interior directly radially inwardly from each of the target assemblies 20. Each protective cover assembly 64 includes cover plate 60 having a sealing gasket or o-ring 62 formed around the entire perimeter thereof which mateably engages against surface 66 of the target assembly 20 so as to completely encase the sacrificial target material 68. The cover 60 is slidably supported on shafts 82 which are themselves supported within a mounting block 86 supported on support plate 58. The support plate 58 is pivotally connected about axis 54.

Each support plate 58 is thus pivotable about the upright axis 54 in the direction of arrow D from an in-use position shown in FIG. 4 in alignment with the corresponding target assembly 20 to a position there away from. Pivotal movement of support plate 58 is accomplished by rotational drivers 74 along axis 54 and 56.

When the cover assemblies 64 are in alignment as shown in FIG. 4 with the target assembly 20, cam 70, acting against moveable plate 78 and compressing return springs 90, force cover plate 60 in the direction of arrow G to effect sealing engagement against surface 66. The cam 70 is rotatably driven in the direction of arrow F by rotational actuator 80 to move the corresponding closure of cover 60. A resilient compression layer 84 is compressed between cover plate 60 and plate 86 to accommodate any spacing irregularity.

The cover 60 is thus sealingly engaged against surface 66 after the chamber 18 has been evacuated of air and the process gas such as argon or nitrous oxide has been introduced into interior 18 of chamber 13 ready for coating of the objects. After the objects have been properly sputter coated for a time sufficient to do so, and before the vacuum and process gas are removed from the chamber 13, cover assembly 64 is pivoted back into the in-use position shown in FIG. 4 in alignment with the sputtering target assembly 20. Then, the cover 60 is moved to sealingly engaged against surface 66 to maintain the vacuum and process gas environment then surrounding the target material 68. Thereafter, the chamber door 22 or 24 is then opened to remove the coated objects and to load a fresh supply of objects previously loaded onto the other one of the corresponding doors 24 or 22 for the next cycle of object sputter coating.

As best seen in FIG. 1, to reduce the time required to replace a target assembly 20, target assemblies in waiting 20a or 20b are prepared and held at the ends of the support rails 26 or 27. Thus, each of the target assemblies 20 which require replacing of the target material 68 may be moved away from the vacuum chamber 12 in the direction of the arrow along one of the support rails 26 or 27 so that the other target assembly in waiting, either 20a or 20b, may be moved into position ready for securement to the vacuum chamber 12.

While the instant invention has been shown and described herein in what are conceived to be the most practical and preferred embodiments, it is recognized that departures may be made therefrom within the scope of the invention, which is therefore not to be limited to the details disclosed herein, but is to be afforded the full scope of the claims so as to embrace any and all equivalent apparatus and articles.

What is claimed is:

1. A sputter coating apparatus comprising:
a vacuum chamber having a sealably closable door through which objects treated by sputter coating are loaded into and removed from said chamber;
a support positionable within said chamber for supporting the objects to be sputter coated;
a vacuum source for establishing a vacuum in said chamber when said door is closed;
a sputtering target formed of a material to be sputter coated onto the objects, said target operably connected within said chamber and spaced apart from the objects;
a process gas inlet operably connected with the interior of said chamber for introducing a process gas into said chamber after a vacuum is established by said vacuum source;
a high voltage source operably connected between the objects on said support within said chamber and said sputtering target and passing through said process gas, said voltage source sufficient to produce an ion plasma formed of some of the material vaporized from said target, said plasma uniformly depositing a coating of the material onto the objects;
a protective cover moveable between a first position away from said target when said door is closed and said apparatus is in operation and a second position sealingly engaged over said target to substantially maintain the vacuum surrounding said target when said door is opened for loading and unloading the objects into and from said chamber.

2. A sputter coating apparatus as set forth in claim 1, further comprising:
a sputtering target in waiting rail suspended and positioned adjacent said chamber for conveyance to said chamber to replace said target when spent.

3. A sputter coating apparatus comprising:
a vacuum chamber having a sealably closable door pivotally connected along one edge of said chamber through which objects treated by sputter coating are loaded into and removed from said chamber;
a support reel connected in spaced relation to an inner side of said door, said reel positioned within said chamber for supporting the objects to be sputter coated when said door is closed;
a vacuum source for establishing a vacuum in said chamber when said door is closed;
a sputtering target formed of a material to be sputter coated onto the objects, said target operably connected within said chamber and spaced apart from the objects;
a process gas inlet operably connected with the interior of said chamber for introducing a process gas into said chamber after a vacuum is established by said vacuum source;
a high voltage source operably connected between the objects on said support within said chamber and said sputtering target and passing through said process gas, said voltage source sufficient to produce an ion plasma formed of some of the material vaporized from said target, said plasma uniformly depositing a coating of the material onto the objects;
a protective cover connected within said chamber for pivotal movement between a first position away from said target when said door is closed and said apparatus is in operation and a second position sealingly engaged over said target to substantially maintain the vacuum surrounding said target when said door is opened for loading and unloading of the objects.

4. A sputter coating apparatus as set forth in claim 3, further comprising:
a sputtering target in waiting rail suspended and positioned adjacent said chamber for conveyance to said chamber to replace said target when spent.

5. A sputter coating apparatus comprising:
an elongated upright vacuum chamber having an opening having upright side margins through which objects to be treated by sputter coating within said chamber are loaded into and removed from said chamber;
a door pivotally connected along each of said side margins in opposing fashion, each said door sealingly closeable one at a time over said opening to establish a sealed interior volume of said chamber;
a support reel rotatably connected in spaced relation to an inner side of each said door, each said reel positionable within said chamber for supporting the objects to be sputter coated when a corresponding said door is closed;
a vacuum source for establishing a vacuum in said chamber when one said door is closed;
an elongated sputtering target generally coextensive with a length of said chamber and formed of a material to be sputter coated onto the objects, said target operably connected within said chamber and spaced apart from the objects;
a process gas inlet operably connected with the interior of said chamber for introducing a process gas into said chamber after a vacuum is established by said vacuum source;
a high voltage source operably connected between the objects on one of said supports within said chamber and said sputtering target and passing through said process gas, said voltage source sufficient to produce an ion plasma formed of some of the material vaporized from said target, said plasma uniformly depositing a coating of the material onto the objects;
a protective cover pivotally moveable between a first position away from said target when said apparatus is in operation and a second position and biased for sealing engagement over said target to substantially maintain the vacuum condition surrounding said target during operation of said apparatus when said door is opened for loading and unloading of the objects and said chamber is not in operation.

6. A sputter coating apparatus as set forth in claim 5, further comprising:
a sputtering target in waiting rail suspended and positioned adjacent said chamber for conveyance to said chamber to replace said target when spent.
